(19) United States
(12) Patent Application Publication
(10) Pub. No.: US 2026/0011584 A1
(43) Pub. Date: Jan. 8, 2026

(54) HEAT TREATMENT APPARATUS, TEMPERATURE CONTROL METHOD, AND INFORMATION PROCESSING APPARATUS

(71) Applicant: Tokyo Electron Limited, Tokyo (JP)

(72) Inventors: Tadamasa OOKA, Yamanashi (JP); Hiroyuki KARASAWA, Yamanashi (JP); Daigo FURUYA, Iwate (JP); Tadashi ENOMOTO, Iwate (JP)

(21) Appl. No.: 19/255,313

(22) Filed: Jun. 30, 2025

(30) Foreign Application Priority Data
Jul. 2, 2024 (JP) 2024-106831

(51) Int. Cl. H01L 21/67

(52) U.S. Cl. CPC H01L 21/67248; H01L 21/67109

(57) ABSTRACT

A heat treatment apparatus includes a processing chamber that heat-treats a substrate, a heating unit that heats the processing chamber from outside, and an internal physical sensor that measures a temperature inside the processing chamber. The heat treatment apparatus further includes a prediction unit that predicts a measurement temperature of an external virtual sensor that is a virtualized version of an external physical sensor that measures a temperature near the heating unit, using a physical model that reproduces a physical configuration of a heat treatment furnace by simulation, and a temperature control unit that controls power supplied to the heating unit based on the measurement temperature of the internal physical sensor and the measurement temperature of the external virtual sensor.

### CROSS-REFERENCE TO RELATED APPLICATIONS

This application is based on and claims priority from Japanese Patent Application No. 2024-106831, filed on Jul. 2, 2024, with the Japan Patent Office, the disclosure of which is incorporated herein in its entirety by reference.

### TECHNICAL FIELD

The present disclosure relates to a heat treatment apparatus, a temperature control method, and an information processing apparatus.

### BACKGROUND

In the related art, a heat treatment apparatus is equipped with a temperature sensor that detects the temperature of a heater and a temperature sensor that detects the temperature inside a processing chamber. The heat treatment apparatus controls the output of the heater based on the signals from the respective temperature sensors so that the temperature of a wafer or the temperature inside the processing chamber reaches a set temperature (see, e.g., Japanese Patent Laid-Open Publication No. 2012-222036).

### SUMMARY

One aspect of the present disclosure is a heat treatment apparatus including a processing chamber that heat-treats a substrate, a heating unit that heats the processing chamber, an internal physical sensor that measures a temperature inside the processing chamber, a prediction unit that predicts a measurement temperature of an external virtual sensor that is a virtualized version of an external physical sensor that measures a temperature near the heating unit, using a physical model that reproduces a physical configuration of a heat treatment furnace by simulation, and a temperature control unit that controls power supplied to the heating unit based on the measurement temperature of the internal physical sensor and the measurement temperature of the external virtual sensor.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a longitudinal-sectional view schematically illustrating a heat treatment apparatus according to an embodiment of the present disclosure.

FIGS. 2A to 2C are diagrams illustrating types of thermocouple (T/C) provided in a heat treatment furnace.

FIG. 3 is a functional block diagram illustrating a controller of a heat treatment apparatus according to an embodiment of the present disclosure.

FIG. 4 is a flowchart illustrating a processing procedure of a heat treatment apparatus according to an embodiment of the present disclosure.

FIG. 5 is a flowchart illustrating a detailed processing procedure of step S16.

FIG. 6 is a block diagram illustrating an information processing system according to an embodiment of the present disclosure.

FIG. 7 is a hardware block diagram illustrating a computer.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the drawings.

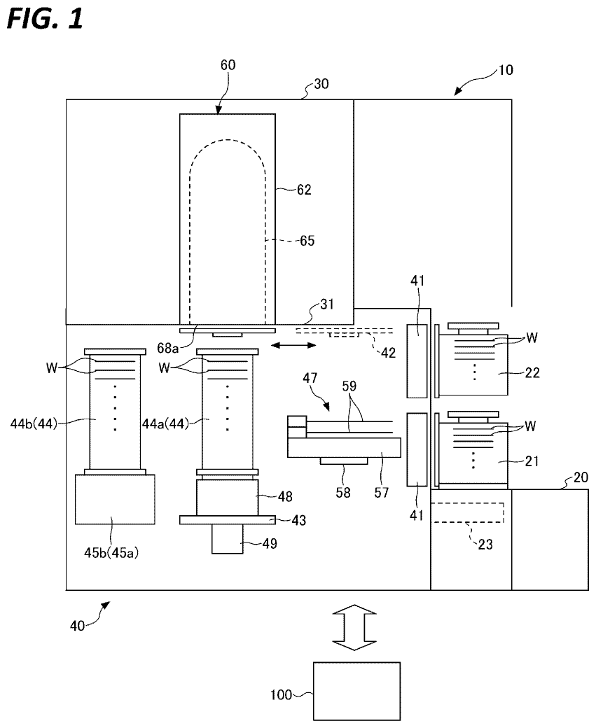

FIG. 1 is a longitudinal-sectional view schematically illustrating a heat treatment apparatus 10 according to an embodiment of the present disclosure. The heat treatment apparatus 10 includes a vertical heat treatment furnace 60, holds and accommodates wafers W in a boat 44 at a predetermined interval along the vertical direction, and is capable of performing various heat treatments such as oxidation, diffusion, and reduced pressure CVD on the wafers W. Hereinafter, heat-treating the surface of the wafer W in the processing chamber 65 by supplying gas into the processing chamber 65 will be described for example. The wafer W is an example of a substrate. The substrate is not limited to a circular wafer W.

The heat treatment apparatus 10 includes a mounting table 20, a housing 30, and a control unit 100. The mounting table 20 is sometimes called a load port. The mounting table 20 is provided at the front of the housing 30. The housing 30 includes a working area 40 and a heat treatment furnace 60.

The working area 40 is sometimes called a loading area. The working area 40 is formed at a lower portion within the housing 30. The heat treatment furnace 60 is provided above the working area 40 within the housing 30. A base plate 31 is provided between the working area 40 and the heat treatment furnace 60.

The mounting table 20 is used to load and unload the wafers W into and from the housing 30. The mounting table 20 is provided with storage containers 21 and 22. Each of the storage containers 21 and 22 is a front-opening unified pod (FOUP) that has a removable lid (not illustrated) on the front and is capable of storing a plurality of wafers W (e.g., about 25 wafers) at a predetermined interval.

In addition, an alignment device 23 may be provided under the mounting table 20 to align cutouts (e.g., notches) formed at the outer periphery of the wafers W transferred by a transfer mechanism 47 in one direction. The alignment device 23 is sometimes called an aligner.

In the working area 40, the wafers W are transferred between the storage containers 21 and 22 and the boat 44. Also, in the working area 40, the boat 44 is loaded into the processing chamber 65 and unloaded from the processing chamber 65. The working area 40 is provided with a door mechanism 41, a shutter mechanism 42, a cover body 43, the boat 44, a base 45a, a base 45b, the transfer mechanism 47, a heat-retaining tube 48, and a lifting mechanism. The lifting mechanism is not illustrated.

The door mechanism 41 disengages the lids of the storage containers 21 and 22, thereby opening the interiors of the storage containers 21 and 22 into the working area 40. The shutter mechanism 42 is provided at an upper portion of the working area 40 so as to cover (or block) a furnace port 68a in order to suppress or prevent heat inside the high-temperature furnace from being released from the furnace port 68a into the working area 40 when the cover body 43 is open.

The cover body 43 has a rotation mechanism 49. The heat-retaining tube 48 is provided on the cover body 43. The heat-retaining tube 48 prevents the boat 44 from being cooled by heat transfer with the cover body 43, thereby keeping the boat 44 warm. The rotation mechanism 49 is attached to the bottom of the cover body 43. The rotation mechanism 49 rotates the boat 44. A rotation shaft of the rotation mechanism 49 is provided to pass through the cover body 43 air-tightly and rotate a turntable arranged on the cover body 43.

The lifting mechanism drives the cover body 43 to move up and down when the boat 44 is loaded from the working area 40 into the processing chamber 65 or unloaded from the processing chamber 65 into the working area 40. When the boat 44 raised by the lifting mechanism has been loaded into the processing chamber 65, the cover body 43 abuts against the furnace port 68a to seal the furnace port 68a.

The boat 44 on the cover body 43 is capable of keeping the wafers W rotatably in a horizontal plane within the processing chamber 65. The heat treatment apparatus 10 may have a plurality of boats 44. In FIG. 1, the boats 44a and 44b are provided in the working area 40. Also, the working area 40 is provided with the base 45a, the base 45b, and a boat transfer mechanism.

The bases 45a and 45b are mounting tables on which the boats 44a and 44b are transferred from the cover body 43, respectively. The boat transfer mechanism transfers the boat 44a or 44b from the cover body 43 onto the base 45a or 45b.

The boats 44a and 44b are made of, for example, quartz, and are capable of mounting large-diameter wafers W, for example, 300 mm in diameter, in a horizontal state at a predetermined interval (pitch width) in the vertical direction. The boats 44a and 44b have a plurality of (e.g., three) support columns between the top and bottom plates. The support columns have claws for holding the wafers W. Also, the boats 44a and 44b may have auxiliary columns suitably in addition to the support columns.

The transfer mechanism 47 transfers the wafers W between the storage container 21 or 22 and the boat 44a or 44b. The transfer mechanism 47 includes a base 57, a lifting arm 58, and a plurality of transfer plates 59. The transfer plate 59 is also referred to as a fork.

The base 57 is provided to rise and fall and to rotate. The lifting arm 58 is provided to move (rise and fall) in the vertical direction by, for example, a ball screw. The base 57 is provided on the lifting arm 58 to be horizontally rotatable.

The heat treatment furnace 60 includes a jacket 62, a processing chamber 65, and a heater. The heater is not illustrated.

The processing chamber 65 accommodates the wafers W held in the boat 44. The wafers W accommodated in the processing chamber 65 are heat-treated. The processing chamber 65 is made of, for example, quartz, and has a vertically long shape. Gas is supplied into the processing chamber 65 through an injector. The gas supplied into the processing chamber 65 is exhausted from an exhaust system.

The cover body 43 may be raised and lowered by the lifting mechanism, and closes the furnace port 68a when the boat 44 is loaded into the processing chamber 65. The heat-retaining tube 48 is disposed on the cover body 43. The boat 44 is provided on the heat-retaining tube 48.

The jacket 62 is provided to envelop the processing chamber 65 and to define a space around the processing chamber 65. The jacket 62 has a cylindrical shape, similar to the processing chamber 65. A heat-insulating material made of, for example, glass wool may be provided inside the jacket 62 and outside the space defined around the processing chamber 65.

The heater is provided to envelop the processing chamber 65. The heater is provided inside the jacket 62 and outside the processing chamber 65. The heater heats the processing chamber 65 and is capable of controlling the heating of the inside of the processing chamber 65 to a predetermined temperature (e.g., 50 to 1200° C.) for each unit area called a zone. The heater heats the wafers W accommodated in the processing chamber 65. The heater is an example of a heating unit that heats the processing chamber 65 from the outside. The heater is configured to control heating by, for example, the output (heater power) of a heater power control unit 86 described below.

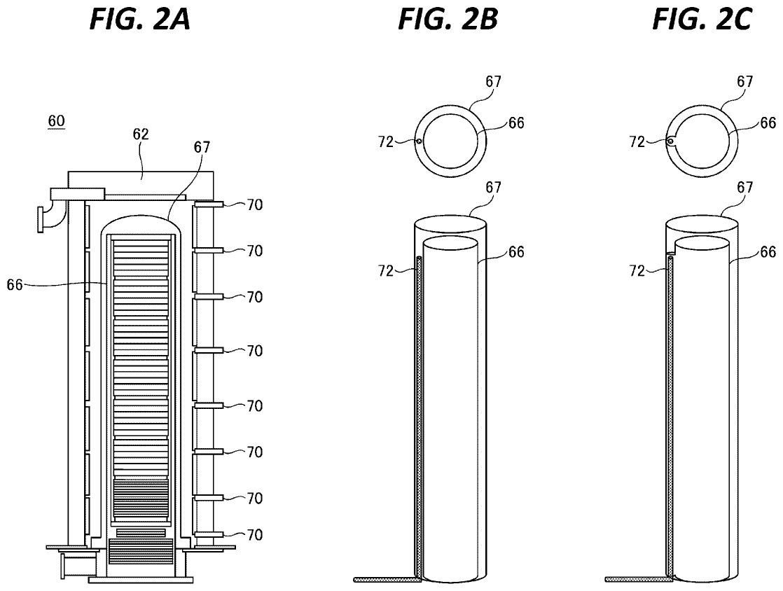

The heat treatment furnace 60 is provided with a thermocouple. The thermocouple is an example of a temperature sensor that measures temperature. The heat treatment furnace 60 is provided with, for example, a thermocouple of the type illustrated in FIGS. 2A to 2C. FIGS. 2A to 2C are diagrams illustrating the types of thermocouple (T/C) provided in the heat treatment furnace 60. The processing chamber 65 includes an inner tube 66 and an outer tube 67.

FIG. 2A is a diagram illustrating an example of the position of an external thermocouple 70. The external thermocouple 70 as illustrated in FIG. 2A measures the temperature near the heater. The external thermocouple 70 is an example of an external physical sensor that measures the temperature near the heater. The external thermocouple 70 includes an outer T/C and an excess T/C. For example, the outer T/C is used to control the temperature of the heater. The excess T/C is used to detect overheating of the heater.

FIG. 2B is a diagram illustrating an example of the position of an internal thermocouple 72. The internal thermocouple 72 as illustrated in FIG. 2B measures the temperature inside the processing chamber 65. The internal thermocouple 72 of FIG. 2B is provided inside the outer tube 67 and outside the inner tube 66. The internal thermocouple 72 as illustrated in FIG. 2B is an example of an internal physical sensor that measures the temperature inside the processing chamber 65, and is, for example, an inner T/C.

FIG. 2C is a diagram illustrating another example of the position of the internal thermocouple 72. The internal thermocouple 72 as illustrated in FIG. 2C measures the temperature inside the processing chamber 65. The internal thermocouple 72 of FIG. 2C is provided inside the inner tube 66. The internal thermocouple 72 as illustrated in FIG. 2C is an example of the internal physical sensor that measures the temperature inside the processing chamber 65, and is, for example, an inside T/C. In the present embodiment, an example using the internal thermocouple 72 as illustrated in FIG. 2C will be described, but the internal thermocouple 72 as illustrated in FIG. 2B may also be used.

The internal thermocouple 72 as illustrated in FIG. 2C is provided inside the inner tube 66, and is therefore capable of measuring the temperature near the wafer W with greater accuracy than the internal thermocouple 72 in FIG. 2B provided outside the inner tube 66.

The temperature measured by the external thermocouple 70 of FIG. 2A has been used in many control modes of the heat treatment apparatus 10. In recent heat treatment apparatus 10, the use of the temperature measured by the external thermocouple 70 has been decreasing. Furthermore, the temperature measured by the external thermocouple 70 is increasingly used for purposes that have little effect on the film formation results of the wafer W, and the required accuracy is also decreasing.

Therefore, in the present embodiment, the external thermocouple 70 that measures the temperature near the heater is virtualized by predicting the measurement temperature of the external thermocouple 70 using a physical model that reproduces the physical configuration of the heat treatment furnace 60 by simulation. The virtualization of the external thermocouple 70 may be performed for all outer T/Cs, or may be performed so that some outer T/Cs are left. The excess T/C may not be virtualized.

Referring back to FIG. 1. The temperatures measured by the external thermocouples 70 that are not virtualized are input to the control unit 100. The temperature measured by the internal thermocouple 72 is input to the control unit 100 as the measurement temperature of the internal physical sensor. Upon receiving the measurement temperatures, the control unit 100 controls the heater power supplied to the heater by the heater power control unit 86 described later. The heater power control unit 86 supplies the heater power adjusted by the control unit 100 to the heater.

The control unit 100 is implemented by, for example, a computer 500 as described below. The control unit 100 reads a program recorded in a storage device, and sends control signals to respective components of the heat treatment apparatus 10 according to the program to perform heat treatment. In addition, for example, the control unit 100 adjusts the heater power supplied to the heater by the heater power control unit 86 as described below, thereby more accurately controlling the temperature of the wafer W loaded into the processing chamber 65.

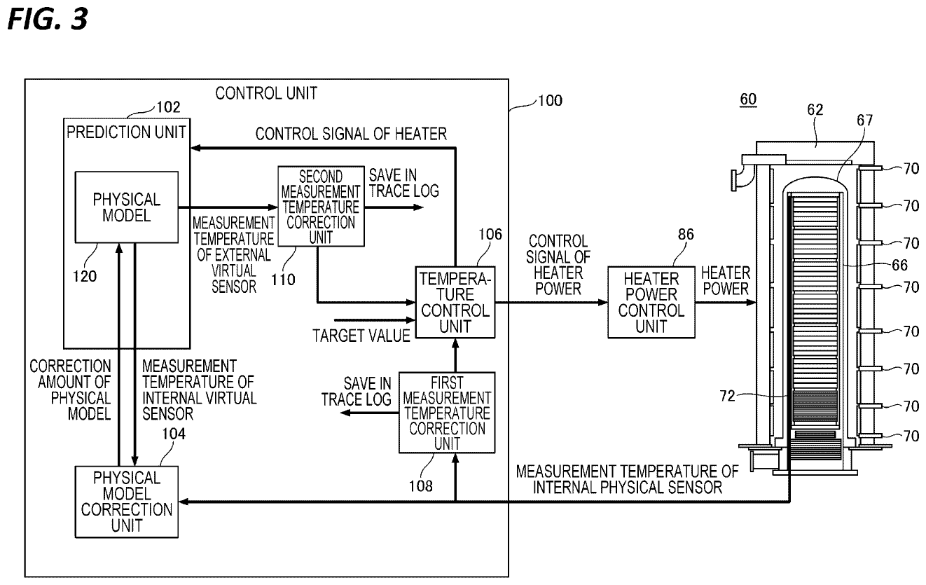

The control unit 100 of the heat treatment apparatus 10 is implemented, for example, by the functional configuration illustrated in FIG. 3. FIG. 3 is a functional block diagram illustrating the control unit 100 of the heat treatment apparatus 10 according to an embodiment of the present disclosure. The functional block diagram of FIG. 3 omits the illustration of components that are not necessary for the description of the present embodiment.

The control unit 100 implements a prediction unit 102, a physical model correction unit 104, a temperature control unit 106, a first measurement temperature correction unit 108, and a second measurement temperature correction unit 110 by executing a program. The prediction unit 102 uses a physical model 120. The physical model 120 reproduces the physical configuration of the heat treatment furnace 60 by simulation, and simulates the behavior of the heat treatment furnace 60. The physical model 120 uses, for example, a thermal simulation model of 1DCAE.

The control unit 100 is an example of an information processing apparatus that controls the temperature inside the processing chamber 65 of the heat treatment apparatus 10. The temperature control unit 106 acquires a set temperature that is a target value according to a process executed in the heat treatment apparatus 10. In addition, the temperature control unit 106 acquires the outputs of the first measurement temperature correction unit 108 and the second measurement temperature correction unit 110.

The first measurement temperature correction unit 108 acquires the temperature measured by the internal thermocouple 72 (e.g., the measurement temperature of the internal physical sensor), and performs offset correction of an auto profile function. In the offset correction, the correction is performed using a temperature difference between a stable temperature of a profile thermocouple provided near the wafer W and the measurement temperature of the internal thermocouple 72. The first measurement temperature correction unit 108 outputs the measurement temperature of the internal thermocouple 72 after correction to the temperature control unit 106. Also, the first measurement temperature correction unit 108 saves the measurement temperature of the internal thermocouple 72 after correction in a trace log.

The second measurement temperature correction unit 110 acquires the measurement temperature of the external virtual sensor, which is the measurement temperature of the external thermocouple 70 predicted by the prediction unit 102, and performs profile correction of the auto profile function. In the profile correction, the correction is performed using a temperature difference between the measurement temperature of the external thermocouple 70 and the measurement temperature of the internal thermocouple 72. The second measurement temperature correction unit 110 outputs the measurement temperature of the external virtual sensor after correction to the temperature control unit 106. Also, the second measurement temperature correction unit 110 saves the measurement temperature of the external virtual sensor after correction in the trace log.

The temperature control unit 106 outputs a heater power control signal to the heater power control unit 86 so that the temperature of the wafer W in the processing chamber 65 approaches the set temperature, which is the target value, based on the set temperature, the corrected measurement temperature of the internal thermocouple 72, and the corrected measurement temperature of the external virtual sensor. The heater power control unit 86 supplies heater power to the heater in accordance with the heater power control signal output from the temperature control unit 106. In this way, the temperature control unit 106 feedback-controls the heater power control unit 86.

In addition, the temperature control unit 106 outputs the heater power control signal output to the heater power control unit 86 to the prediction unit 102. The prediction unit 102 predicts the measurement temperature of the external virtual sensor obtained by virtualizing the external thermocouple 70 and the measurement temperature of the internal virtual sensor obtained by virtualizing the internal thermocouple 72, using the physical model 120. The physical model 120 outputs the measurement temperature of the external virtual sensor and the measurement temperature of the internal virtual sensor according to the heater power.

For example, the prediction unit 102 is capable of outputting the measurement temperature of the external virtual sensor and the measurement temperature of the internal virtual sensor according to the heater power by using the physical model 120, which is a thermal simulation model of 1DCAE that reproduces the configuration of the heat treatment furnace 60 of the heat treatment apparatus 10. The physical model 120, which is the 1DCAE thermal simulation model, models the heat exchange relationships and specific heats of components such as the members of the heat treatment furnace 60 and the wafer W.

The prediction unit 102 outputs the measurement temperature of the external virtual sensor predicted according to the heater power to the second measurement temperature correction unit 110. Furthermore, the prediction unit 102 outputs the measurement temperature of the internal virtual sensor predicted according to the heater power to the physical model correction unit 104.

The physical model correction unit 104 acquires the temperature measured by the internal thermocouple 72 (e.g., the measurement temperature of the internal physical sensor). In addition, the physical model correction unit 104 acquires the measurement temperature of the internal virtual sensor predicted by the prediction unit 102 using the physical model 120.

The physical model correction unit 104 corrects the physical model 120 based on a difference (e.g., an actual-versus-predicted difference) between the measurement temperature of the internal physical sensor and the measurement temperature of the internal virtual sensor. For example, the physical model correction unit 104 calculates the correction amount of the physical model 120 based on the difference between the measurement temperature of the internal physical sensor and the measurement temperature of the internal virtual sensor. The physical model correction unit 104 corrects the physical model of the prediction unit 102 by outputting the calculated correction amount of the physical model 120 to the prediction unit 102.

In the heat treatment apparatus 10 according to the present embodiment, the physical model 120 is corrected by feeding back the difference between the measurement temperature of the internal physical sensor and the measurement temperature of the internal virtual sensor to the physical model 120, so that the measurement temperature of the internal physical sensor and the measurement temperature of the internal virtual sensor approach each other. As illustrated in FIG. 3, in the heat treatment apparatus 10 according to the present embodiment, the measurement temperature of the external thermocouple 70 is not used to correct the physical model 120.

In the meantime, due to the effect of correcting the physical model 120 based on the difference between the measurement temperature of the internal physical sensor and the measurement temperature of the internal virtual sensor, the measurement temperature of the external virtual sensor predicted according to the heater power approaches the temperature measured (actually measured) by the external thermocouple 70. By thus correcting the physical model 120 based on the difference between the measurement temperature of the internal physical sensor and the measurement temperature of the internal virtual sensor, the prediction accuracy of the measurement temperature of the external virtual sensor is indirectly improved.

In the heat treatment apparatus 10 according to the present embodiment, the temperature measured by the external thermocouple 70 is not used to correct the physical model 120. Therefore, even if at least a portion (all or a portion) of the external thermocouples 70 are omitted, the physical model 120 may be corrected to improve the accuracy of the measurement temperature of the external virtual sensor predicted by the prediction unit 102.

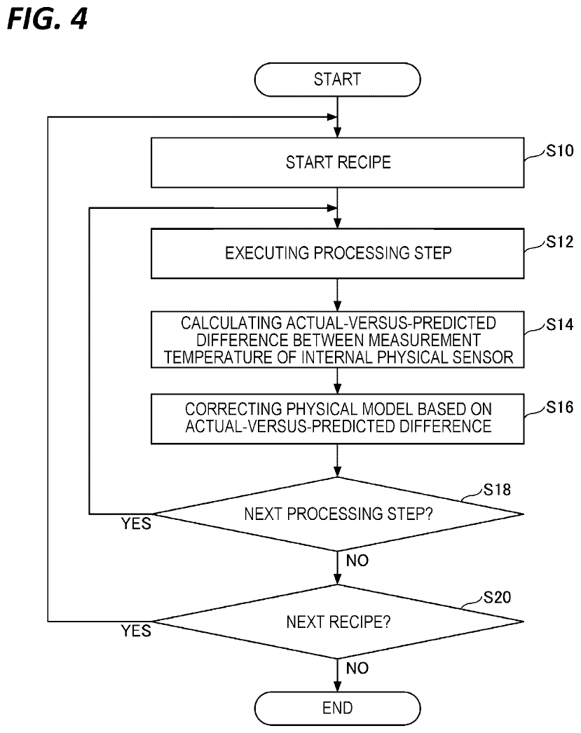

FIG. 4 is a flowchart illustrating a processing procedure of the heat treatment apparatus 10 according to an embodiment of the present disclosure.

In step S10, the heat treatment apparatus 10 starts a process according to a recipe. The recipe for the heat treatment apparatus 10 divides the process into a plurality of processing steps (sections). The recipe sets the order of the processing steps to be executed and parameters for each processing step. In step S12, the heat treatment apparatus 10 executes the processing steps according to the recipe.

In step S14, the physical model correction unit 104 of the control unit 100 acquires the temperature measured by the internal thermocouple 72 (e.g., the measurement temperature of the internal physical sensor) during the execution of the processing step, and the measurement temperature of the internal virtual sensor during the execution of the processing step, which is predicted by the prediction unit 102 using the physical model 120. The physical model correction unit 104 then calculates the difference (e.g., the actual-versus-predicted difference) between the measurement temperature of the internal physical sensor and the measurement temperature of the internal virtual sensor.

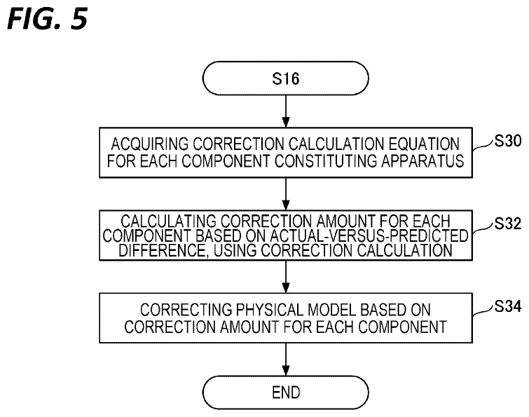

In step S16, the physical model correction unit 104 corrects the physical model 120 based on the actual-versus-predicted difference calculated in step S14. The processing of step S16 is executed, for example, as illustrated in FIG. 5.

FIG. 5 is a flowchart illustrating a detailed processing procedure of step S16.

In step S30, the physical model correction unit 104 acquires a correction calculation equation which is set for each component constituting the heat treatment furnace 60. The components for which the correction calculation equation is set are, for example, the heat-insulating material, heater, inner tube 66, outer tube 67, inside T/C, inner T/C, outer T/C, T/C tube, wafer edge, and wafer center that constitute the heat treatment furnace 60.

The correction calculation equation is configured as in, for example, Equation 1 below.

Correction amount for each component=Actual-versus-predicted difference×Adjustment value for each component [Equation 1]

The adjustment value for each component may include an adjustment value common to respective components and an adjustment value for each component. The correction calculation equation for the outer tube 67 may be used as the correction calculation equation for the outer T/C.

In step S32, the physical model correction unit 104 calculates the correction amount for each component constituting the heat treatment furnace 60 based on the actual-versus-predicted difference, using the correction calculation equation illustrated in Equation 1.

In step S34, the physical model correction unit 104 corrects the physical model 120 based on the correction amount for each component calculated in step S32.

According to the process of the flowchart as illustrated in FIG. 5, the physical model correction unit 104 may calculate the correction amount for each component based on the actual-versus-predicted difference, using the correction calculation equation set for each component constituting the heat treatment furnace 60, and correct the physical model 120 based on the calculated correction amount.

Returning to step S18 in FIG. 4, when the recipe started in step S10 has a next processing step, the heat treatment apparatus 10 returns to step S12 and executes the next processing step. When there is no next processing step, the heat treatment apparatus 10 determines in step S20 whether there is a next recipe. When there is a next recipe, the heat treatment apparatus 10 returns to step S10 and starts the next recipe. When there is no next recipe, the heat treatment apparatus 10 ends the process of the flowchart in FIG. 4.

In the process of the flowchart in FIG. 4, the physical model 120 may be corrected, for each processing step of the recipe, based on the difference between the measurement temperature of the internal virtual sensor predicted using the physical model 120 and the measurement temperature of the internal physical sensor.

In the heat treatment apparatus 10 according to the present embodiment, at least some of the external thermocouples 70 that measure the temperature near the heater may be virtualized. In addition, in the heat treatment apparatus 10 according to the present embodiment, the effect of correcting the physical model 120 based on the actual-versus-predicted difference of the internal thermocouples 72 may improve the prediction accuracy of the measurement temperature of the external virtual sensor corresponding to the external thermocouple 70.

In the heat treatment apparatus 10 according to the present embodiment, all the external thermocouples 70 may be virtualized and all the virtualized external thermocouples 70 may be omitted, or some of the virtualized external thermocouples 70 may be omitted.

The heat treatment apparatus 10 in which the external thermocouples 70 are replaced with external virtual sensors eliminates the need for the virtualized external thermocouples 70, thus reducing the effort required to replace a failed external thermocouple 70. Consequently, the heat treatment apparatus 10 according to the present embodiment is expected to improve productivity. Furthermore, the heat treatment apparatus 10 according to the present embodiment is expected to reduce the cost of the external thermocouple 70.

Furthermore, in the heat treatment apparatus 10 according to the present embodiment, if some of the external thermocouples 70 remain without being virtualized, the failed external thermocouples 70 may be sequentially replaced with external virtual sensors for operation.

Furthermore, in the heat treatment apparatus 10 according to the present embodiment, if some of the external thermocouples 70 remain without being virtualized, the measurement temperatures of the remaining external thermocouples 70 may be used to correct the physical model 120.

In the above-described embodiment, the processing performed by the control unit 100 of the heat treatment apparatus 10 may be executed by another information processing apparatus connected to the control unit 100 so as to be capable of data communication.

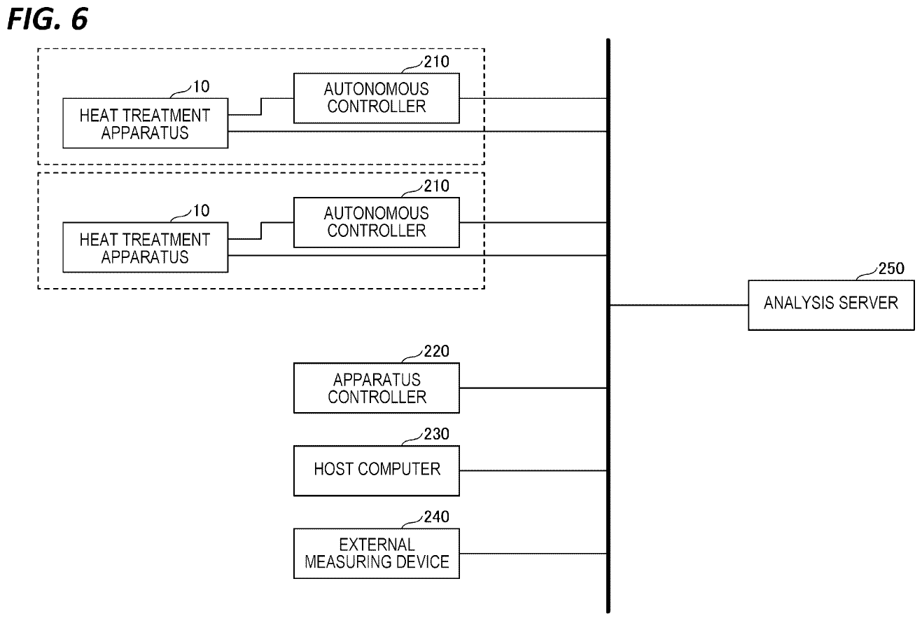

FIG. 6 is a block diagram illustrating an information processing system according to an embodiment of the present disclosure. The information processing system illustrated in FIG. 6 includes the heat treatment apparatus 10, an autonomous controller 210, an apparatus controller 220, a host computer 230, an external measuring device 240, and an analysis server 250.

The heat treatment apparatus 10, the autonomous controller 210, the apparatus controller 220, the host computer 230, the external measuring device 240, and the analysis server 250 are connected to each other so as to be able to communicate with each other via a network such as a local area network (LAN).

The heat treatment apparatus 10 executes a process according to a control command (e.g., a process parameter) output from the apparatus controller 220. The autonomous controller 210 is a controller for autonomously controlling the heat treatment apparatus 10, and performs a simulation of the process state being executed in the heat treatment apparatus 10 using a simulation model.

The autonomous controller 210 is provided for each heat treatment apparatus 10. The autonomous controller 210 executes at least a part of the processing performed by the control unit 100 in the above-described embodiment.

The apparatus controller 220 is a controller having a computer configuration for controlling the heat treatment apparatus 10. The apparatus controller 220 outputs process parameters to the heat treatment apparatus 10 to control the control components of the heat treatment apparatus 10. The host computer 230 is an example of a man-machine interface (MMI) that receives instructions for the heat treatment apparatus 10 from an operator and provides information about the heat treatment apparatus 10 to the operator.

The external measuring device 240 is a measuring device that measures the results after a process is executed according to the process parameters, such as a film thickness measuring device, a sheet resistance measuring device, and a particle measuring device. For example, the external measuring device 240 measures an adhesion state of a film on the wafer W such as a monitor wafer.

The analysis server 250 performs data analysis required for the processing executed by the autonomous controller 210. The analysis server 250 may be configured to modify the physical model 120 of the heat treatment apparatus 10 using data collected from a plurality of heat treatment apparatuses 10.

The information processing system as illustrated in FIG. 6 is just an example, and various system configurations are possible depending on the application and purpose. The classification of devices such as the heat treatment apparatus 10, the autonomous controller 210, the apparatus controller 220, the host computer 230, the external measuring device 240, and the analysis server 250 in FIG. 6 is also merely an example.

For example, the information processing system may have various configurations, such as a configuration in which at least two of the heat treatment apparatus 10, the autonomous controller 210, the apparatus controller 220, the host computer 230, the external measuring device 240, and the analysis server 250 are integrated, or further divided.

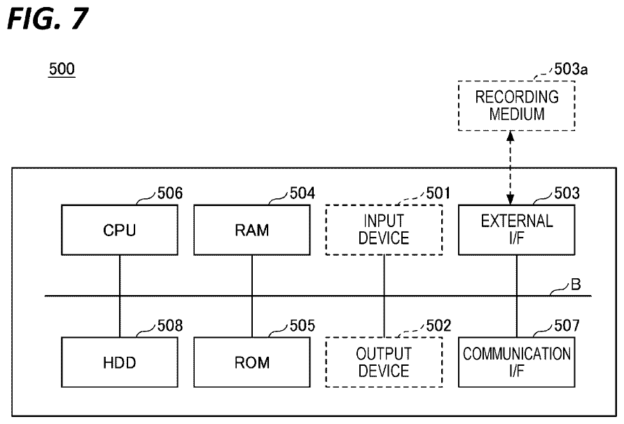

The autonomous controller 210, the apparatus controller 220, the host computer 230, and the analysis server 250 of the information processing system illustrated as illustrated in FIG. 6 are implemented by, for example, a computer having the hardware configuration as illustrated in FIG. 7. The control unit 100 of the heat treatment apparatus 10 described above is also implemented by a computer having the hardware configuration illustrated in FIG. 7. FIG. 7 is a hardware block diagram illustrating a computer.

The autonomous controller 210, the apparatus controller 220, the host computer 230, the analysis server 250, and the control unit 100 constitute an example of the information processing apparatus that performs the temperature control inside the processing chamber 65 of the heat processing apparatus 10.

The computer 500 as illustrated in FIG. 7 includes an input device 501, an output device 502, an external interface (I/F) 503, a random access memory (RAM) 504, a read only memory (ROM) 505, a central processing unit (CPU) 506, a communication I/F 507, and a hard disk drive (HDD) 508, all of which are interconnected via a bus B. The input device 501 and the output device 502 may be connected and used when necessary.

The input device 501 is a keyboard, a mouse, a touch panel, or the like, and is used by an operator, etc. to input various manipulation signals. The output device 502 is a display or the like, and displays the results of processing by the computer 500. The communication I/F 507 is an interface that connects the computer 500 to a network. The HDD 508 is an example of a non-volatile storage device that stores programs and data.

The external I/F 503 is an interface with an external device. The computer 500 may perform reading and/or writing on a recording medium 503a such as a secure digital (SD) memory card via the external I/F 503. The ROM 505 is an example of a non-volatile semiconductor memory (a storage device) that stores programs and data. The RAM 504 is an example of a volatile semiconductor memory (a storage device) that temporarily holds programs and data.

The CPU 506 is a processing device that implements the entire control and functions of the computer 500 by reading programs and data from storage devices such as the ROM 505 and the HDD 508 into the RAM 504 and then executing the processing.

The autonomous controller 210, the apparatus controller 220, the host computer 230, and the analysis server 250 of the information processing system as illustrated in FIG. 6 may implements various functions by the hardware configuration of the computer 500 as illustrated in FIG. 7. In addition, the control unit 100 of the heat treatment apparatus 10 described above may implement various functions by the hardware configuration of the computer 500 in FIG. 7.

By utilizing the technology of the above-described embodiment, the heat treatment apparatus 10 according to the present embodiment may virtualize the external physical sensor that measures the temperature near the heater of the heat treatment apparatus 10.

According to the present disclosure, the external physical sensor that measures the temperature near the heating unit of the heat treatment apparatus may be virtualized.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A heat treatment apparatus comprising:
a processing chamber configured to heat-treat a substrate;
a heater configured to heat the processing chamber from outside;
an internal physical sensor configured to measure a temperature inside the processing chamber; and
a controller configured to control a temperature of the heat treatment apparatus,
wherein the controller is configure to:
predict a measurement temperature of an external virtual sensor that is a virtualized version of an external physical sensor that measures a temperature near the heater, using a physical model that reproduces a physical configuration of a heat treatment furnace by simulation; and
control power supplied to the heater based on the temperature measured by the internal physical sensor and the measurement temperature of the external virtual sensor.

2. The heat treatment apparatus according to claim 1, wherein the controller is further configured to:
correct the physical model based on a difference between a measurement temperature of an internal virtual sensor predicted using the physical model and the temperature measured by the internal physical sensor.

3. The heat treatment apparatus according to claim 2, wherein the controller is configure to, using a correction calculation equation set for each component constituting the heat treatment furnace, calculate a correction amount for each component based on the difference, and correct the physical model based on the correction amount.

4. The heat treatment apparatus according to claim 1, wherein the processing chamber includes an inner tube and an outer tube, and the internal physical sensor is a physical temperature sensor located inside the inner tube.

5. The heat treatment apparatus according to claim 1, wherein at least a portion of the external physical sensor corresponding to the external virtual sensor is omitted.

6. A temperature control method comprising:
providing a heat treatment apparatus including a processing chamber configured to heat-treat a substrate, a heater configured to heat the processing chamber from outside, and an internal physical sensor configured to measure a temperature inside the processing chamber;
predicting a measurement temperature of an external virtual sensor that is a virtualized version of an external physical sensor that measures a temperature near the heater, using a physical model that reproduces a physical configuration of a heat treatment furnace by simulation; and
controlling power supplied to the heater based on the temperature measured by the internal physical sensor and the measurement temperature of the external virtual sensor.

7. An information processing apparatus performing a temperature control of a heat treatment apparatus including a processing chamber configured to heat-treat a substrate, a heater configured to heat the processing chamber from outside, and an internal physical sensor configured to measure a temperature inside the processing chamber, the information processing apparatus comprising:
prediction circuitry configured to predict a measurement temperature of an external virtual sensor that is a virtualized version of an external physical sensor that measures a temperature near the heater, using a physical model that reproduces a physical configuration of a heat treatment furnace by simulation; and
temperature control circuitry configured to control power supplied to the heating unit based on the temperature measured by the internal physical sensor and the measurement temperature of the external virtual sensor.
